(19) United States
(12) Patent Application Publication
(10) Pub. No.: US 2025/0054813 A1
(43) Pub. Date: Feb. 13, 2025

(54) METHOD OF PREPARING SEMICONDUCTOR CHIP, SEMICONDUCTOR CHIP, AND APPARATUS FOR MANUFACTURING SEMICONDUCTOR CHIP

(71) Applicants: SAMSUNG ELECTRONICS CO., LTD., Suwon-si (KR); CHUNGBUK NATIONAL UNIVERSITY INDUSTRY-ACADEMIC COOPERATION FOUNDATION, Cheongju-si (KR)

(72) Inventors: Kyungwook HWANG, Suwon-si (KR); Jaewook JEONG, Ansan-si (KR); Jonghyun JEONG, Ansan-si (KR); Minchul YU, Suwon-si (KR); Sanghoon SONG, Suwon-si (KR); Dongho KIM, Suwon-si (KR); Joonyong PARK, Suwon-si (KR); Youngtek OH, Suwon-si (KR); Junsik HWANG, Suwon-si (KR)

(73) Assignees: SAMSUNG ELECTRONICS CO., LTD., Suwon-si (KR); CHUNGBUK NATIONAL UNIVERSITY INDUSTRY-ACADEMIC COOPERATION FOUNDATION, Cheongju-si (KR)

(21) Appl. No.: 18/795,805

(22) Filed: Aug. 6, 2024

(30) Foreign Application Priority Data
Aug. 7, 2023 (KR) 10-2023-0103131

(51) Int. Cl. H01L 21/78; H01L 21/306; H01L 21/67; H01L 33/00; H01L 33/22

(52) U.S. Cl. CPC H01L 21/7813; H01L 21/30612; H01L 21/67075; H01L 21/67271; H01L 33/0075; H01L 33/22

(57) ABSTRACT

Provided are a semiconductor chip, a method of preparing a semiconductor chip, and an apparatus for manufacturing a semiconductor chip. The method includes separating a semiconductor chip from a laminate, the laminate including a substrate, a lift-off layer on the substrate, and a semiconductor layer on the lift-off layer. The method further includes removing the lift-off layer with an etchant by applying a magnetic field while contacting the laminate and the etchant, to thereby prepare a semiconductor chip.

### CROSS-REFERENCE TO RELATED APPLICATION

This application is based on and claims priority under 35 U.S.C. § 119 to Korean Patent Application No. 10-2023-0103131, filed on Aug. 7, 2023, in the Korean Intellectual Property Office, the disclosure of which is incorporated by reference herein in its entirety.

### BACKGROUND

### 1. Field

The disclosure relates to a semiconductor chip, a method of preparing a semiconductor chip, and an apparatus for manufacturing a semiconductor chip.

### 2. Description of the Related Art

Recently, the demand for light-emitting diodes (LEDs) has been increasing due to advantages, such as low power consumption and environmental friendliness provided by LEDs. For example, semiconductor LED chips are used in display devices and the like.

A semiconductor LED chip may be manufactured through a process of forming a semiconductor layer on a substrate to prepare a laminate, and then peeling a semiconductor chip from the substrate by etching.

However, the peeled semiconductor chip may contain a defect caused by etching. Moreover, the peeled semiconductor chips may aggregate together or adhere to the substrates, and as such, it may be difficult to apply to the subsequent processes to the peeled semiconductor chips, such as a transfer process.

### SUMMARY

According to an aspect of the disclosure, there is provided a method of controlling an etching time to suppress defects in semiconductor chips that occur during an etching process.

According to an aspect of the disclosure, there is provided a method for controlling the surface roughness of the peel-off surface of a semiconductor chip to prevent the peeled semiconductor chips from aggregating together or adhering to the substrates.

According to an aspect of the disclosure, there is provided a method of preparing a semiconductor chip in which, by applying a magnetic field during an etching process, the etching time and the surface roughness of a peel-off surface of a semiconductor chip may be controlled.

According to an aspect of the disclosure, there is provided a semiconductor chip prepared by the method.

According to an aspect of the disclosure, there is provided an apparatus for manufacturing the semiconductor chip.

According to an aspect of the disclosure, there is provided a method of manufacturing a semiconductor chip, the method including: providing a laminate into a chamber, the laminate including a substrate, a lift-off layer on the substrate and a semiconductor layer on the lift-off layer; providing an etchant into the chamber; removing the lift-off layer with the etchant by applying a magnetic field while the laminate and the etchant are in contact with each other, wherein the semiconductor layer forms the semiconductor chip after the lift-off layer is removed.

According to another aspect of the disclosure, there is provided a semiconductor chip including: a bottom layer having a first surface and second surface facing a direction opposite to the first surface; and an upper semiconductor layer provided on the second surface of the bottom layer, wherein the first surface of the bottom layer has a root mean square (RMS) surface roughness Rq of 1 nm or more, and wherein the RMS surface roughness Rq of the first surface of the bottom layer is 50% or less of a thickness of the bottom layer.

According to another aspect of the disclosure, there is provided an apparatus for manufacturing a semiconductor chip, the apparatus including: a first chamber configured to house an etchant and a laminate including a substrate, a lift-off layer on the substrate and a semiconductor layer on the lift-off layer; one or more rotatable magnetic rotors configured to induce a changing magnetic field; and a controller configured to control the one or more rotatable magnetic rotors to apply the changing magnetic field while the etchant and the laminate are in contact with each other in the first chamber, and wherein the one or more rotatable magnetic rotors are provided inside the first chamber or adjacent to an outer surface of the first chamber.

Additional aspects will be set forth in part in the description which follows and, in part, will be apparent from the description, or may be learned by practice of the presented embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a schematic diagram of an apparatus for manufacturing a semiconductor chip according to an embodiment;

FIG. 2 is a schematic diagram of an apparatus for manufacturing a semiconductor chip according to an embodiment;

FIG. 3 is a schematic diagram of an apparatus for manufacturing a semiconductor chip according to an embodiment;

FIG. 4 is a schematic diagram of an apparatus for manufacturing a semiconductor chip according to an embodiment;

FIG. 5 is a schematic diagram of an apparatus for manufacturing a semiconductor chip according to an embodiment;

FIG. 6 is a schematic diagram of an apparatus for manufacturing a semiconductor chip according to an embodiment;

FIG. 7 is a schematic diagram of an apparatus for manufacturing a semiconductor chip according to an embodiment;

FIG. 8 is a schematic diagram of an apparatus for manufacturing a semiconductor chip according to an embodiment;

FIG. 9 is a schematic diagram of a semiconductor chip according to an embodiment;

FIG. 10A is an atomic force microscopy (AFM) image of a bottom surface of the semiconductor chip prepared in Example 1;

FIG. 10B is an AFM image of a bottom surface of the semiconductor chip prepared in Example 2;

FIG. 10C is an AFM image of a bottom surface of the semiconductor chip prepared in Example 3;

FIG. 11 is a graph showing a surface roughness of a bottom surface of the semiconductor chips prepared in Examples 1 to 3 according to magnetic field magnitude;

FIG. 12A is an AFM image of a surface of the semiconductor chip manufactured in Example 5, FIG. 12B is an image of a transfer substrate after primary transfer, FIG. 12C is an image of a transfer substrate after secondary transfer, and FIG. 12D an image of a PDMS sheet after secondary transfer;

FIG. 13A is an AFM image of a surface of the semiconductor chip manufactured in Example 6, FIG. 13B is an image of a transfer substrate after primary transfer, FIG. 13C is an image of a transfer substrate after secondary transfer, and FIG. 13D is an image of a PDMS sheet after secondary transfer;

FIG. 14A is an AFM image of a surface of the semiconductor chip manufactured in Comparative Example 2, FIG. 14B is an image of a transfer substrate after primary transfer, FIG. 14C is an image of a transfer substrate after secondary transfer, and FIG. 14D is an image of a PDMS sheet after secondary transfer; and

FIG. 15A is an AFM image of a surface of the semiconductor chip manufactured in Comparative Example 3, FIG. 15B is an image of a transfer substrate after primary transfer, FIG. 15C is an image of a transfer substrate after secondary transfer, and FIG. 15D is an image of a PDMS sheet after secondary transfer.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The disclosure, which will be more fully described hereinafter, may have various variations and various embodiments, and specific embodiments will be illustrated in the accompanied drawings and described in greater detail. However, the disclosure should not be construed as being limited to specific embodiments set forth herein. Rather, these embodiments are to be understood as encompassing all variations, equivalents, or alternatives included in the scope of the disclosure.

The terminology used hereinbelow is used for the purpose of describing particular embodiments only and is not intended to limit the disclosure. As used herein, the singular forms are intended to include the plural forms as well, unless the context clearly indicates otherwise. As used herein, the terms “comprises” and/or “comprising,” or “includes” and/or “including” specify the presence of stated features, regions, integers, steps, operations, elements, components, ingredients, materials, or combinations thereof, but do not preclude the presence or addition of one or more other features, regions, integers, steps, operations, elements, components, ingredients, materials, or combinations thereof. As used herein, “/” may be interpreted as “and”, or as “or” depending on the context.

In the drawings, the thicknesses of layers and regions may be exaggerated for clarity of description. Like reference numerals denote like elements throughout the specification. Throughout the specification, when a component, such as a layer, a film, a region, or a plate, is described as being “above” or “on” another component, the component may be directly above the another component, or there may be yet another component therebetween. It will be understood that although the terms “first,” “second,” etc. may be used herein to describe various elements, these elements should not be limited by these terms. These terms are only used to distinguish one element from another element. In the present specification and the drawings, elements that serve substantially the same function are labeled with the same reference numeral and may not be discussed redundantly.

Hereinafter, a semiconductor chip, a method of preparing a semiconductor chip, and an apparatus for manufacturing a semiconductor chip according to embodiments will be described in greater detail.

A method of manufacturing a semiconductor chip according to an embodiment may include separating a semiconductor chip from a laminate, which includes a substrate, a lift-off layer on the substrate, and a semiconductor layer on the lift-off layer. The method may include preparing a semiconductor by removing the lift-off layer with an etchant by applying a magnetic field while contacting the laminate and the etchant. In semiconductor chips manufactured using this method, defect formation may be suppressed. Semiconductor chips prepared by the method may show improved productivity because during the subsequent processes, peeled semiconductor chips are prevented from adhering to substrates and the peeled semiconductor chips are prevented from aggregating together.

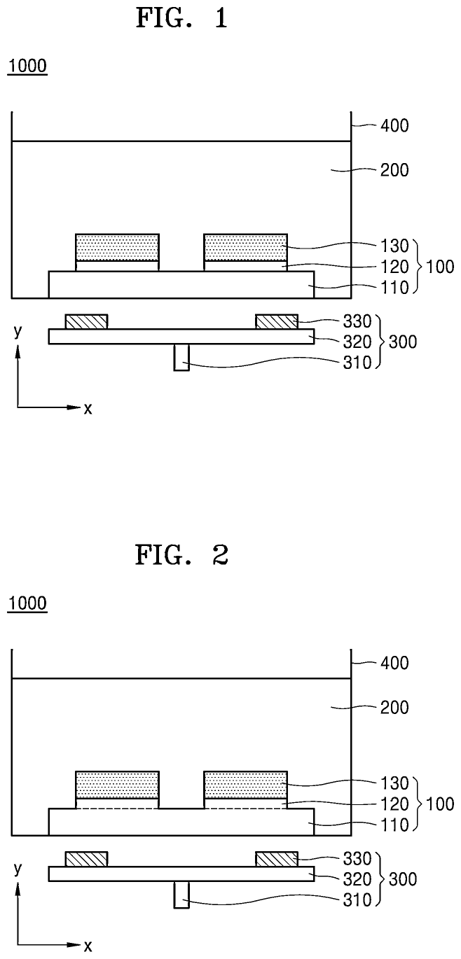

FIGS. 1 to 8 are diagrams for describing a method of manufacturing a semiconductor chip according to an embodiment.

Referring to FIGS. 1 to 8, a method of manufacturing a semiconductor chip according to an embodiment will be described.

According to an embodiment, the method of manufacturing a semiconductor chip 140 (FIG. 4) may include forming a semiconductor chip 140 from a laminate 100. The laminate may include a substrate 110, a lift-off layer 120 provided on the substrate 110 and a semiconductor layer 130 provided on the lift-off layer 120. The semiconductor chip 140 may be formed by applying a magnetic field while the laminate 100 and an etchant 200 are in contact with each other, and then removing the lift-off layer 120 with the etchant 200. By applying a magnetic field while the laminate 100 and the etchant 200 are in contact with each other, the etching rate of the lift-off layer 120 may increase, and the surface roughness of a bottom surface 140a of the semiconductor chip 140 may increase.

The mechanism by which the magnetic field increases the etching rate of the lift-off layer 120 and increases the surface roughness of the bottom surface 140a of the semiconductor chip 140 will be described below to provide a better understanding of the disclosure. However, this should not be construed as limiting the scope of the disclosure in any manner. As such, according to another embodiment, various other mechanisms may be used to increases the etching rate of the lift-off layer 120. According to an embodiment, by applying a magnetic field to the etchant 200 and/or the laminate 100 while the lift-off layer 120 is being dissolved, a magnetic force resulting from the magnetic field may act on one or more of the semiconductor layer 130, metal ions, semiconductor ions, metal particles, and semiconductor particles dissolved in the etchant 200. Therefore, in addition to a chemical reaction that occurs during the etching process, physical interferences, e.g., physical perturbation may be additionally generated by the by-products such as metal ions, semiconductor ions, metal particles, and semiconductor particles generated from the etching process and/or the semiconductor layer 130, and thus, the removal rate of the lift-off layer 120 may increase. Moreover, the surface roughness of the bottom surface 140a of the semiconductor chip 140 obtained by removal of the lift-off layer 120 may increase. In addition, by controlling the level of such physical interferences, the removal rate of the lift-off layer 120 and/or the surface roughness of the bottom surface 140a of the semiconductor chip 140 may be controlled.

The magnitude of the magnetic field may be, for example, 100 G or more, 200 G or more, 300 G or more, 500 G or more, 1,000 G or more, or 1,500 G or more. G represents the unit of magnetic field, i.e., Gauss. The magnitude of the magnetic field may be, for example, about 100 G to about 1,000 G, about 200 G to about 10,000 G, about 300 G to about 9,000 G, about 500 G to about 8,000 G, about 1,000 G to about 7,000 G, or about 1,500 G to about 5,000 G. With the magnitude of the magnetic field having these ranges, the etching rate of the lift-off layer 120 and/or the surface roughness of the bottom surface 140a of the semiconductor chip 140 being prepared may be more easily controlled. The bottom surface 140a of the semiconductor chip 140 may be, for example, a peel-off surface of the semiconductor layer 130. In an example case in which the magnitude of the magnetic field decreases excessively, the effect due to the magnetic field may be insignificant.

According to an embodiment, the magnetic field may include a changing magnetic field. The changing magnetic field may further increase the etching rate of the lift-off layer 120 and further increase the surface roughness of the bottom surface 140a of the semiconductor chip 140 being prepared. For example, the changing magnetic field may include a change in a direction and/or a magnitude of the magnetic field. For example, the direction or the magnitude may change over time and/or change based on a location. The changing magnetic field may change, for example, periodically or non-periodically. Because the magnetic field changes periodically or non-periodically, the etching rate of the lift-off layer 120 and/or the surface roughness of the bottom surface 140a of the semiconductor chip 140 being prepared may be more easily controlled. The changing magnetic field may change, for example, regularly or irregularly. Because the magnetic field changes regularly or irregularly, the etching rate of the lift-off layer 120 and/or the surface roughness of the bottom surface 140a of the semiconductor chip 140 being prepared may be more easily controlled.

The changing magnetic field may be induced by, for example, a magnetic rotor 300. However, the disclosure is not limited thereto, and as such, the magnetic field may be varied by using another mechanism. The magnetic rotor 300 may include a rotating shaft 310, a support portion 320 extending in a width direction perpendicular to an axial direction of the rotating shaft 310, and a magnet 330 provided on the support portion 320. The magnet 330 may be, for example, a permanent magnet. According to an embodiment, the magnetic rotor 300 may include a magnetic bar. Because the magnet 330 is rotated with rotation of the magnetic rotor 300, the direction and magnitude of the magnetic field may change over time. Due to rotation of the magnetic rotor 300, the magnetic field may also rotate. The magnetic rotor 300 may rotate, for example, periodically or non-periodically. As such, a change to the magnetic field may be induced periodically or non-periodically. In an example case in which the rotation of the magnetic rotor 300 is periodic, a change to the magnetic field may be induced periodically. In an example case in which the rotation of the magnetic rotor 300 is non-periodic (aperiodic), a change to the magnetic field may be induced non-periodically (aperiodically). The magnetic rotor 300 may rotate, for example, regularly or irregularly. As such, a change to the magnetic field may be induced regular or irregular. For example, in a case in which the rotation of the magnetic rotor 300 is regular, the magnetic field may be changed regularly. In an example case in which the rotation of the magnetic rotor 300 is irregular, the magnetic field may be changed irregularly. A magnetic bar may be rotated by a magnetic field induced by another magnetic rotor 300, and as such, may additionally induce a changing magnetic field.

The rotation rate of the magnetic rotor 300 may be, for example, 100 rpm or more, 200 rpm or more, 300 rpm or more, or 500 rpm or more. The rotation rate of the magnetic rotor 300 may be, for example, about 100 rpm to about 10,000 rpm, about 200 rpm to about 5,000 rpm, about 300 rpm to about 3,000 rpm, or about 500 rpm to about 20,000 rpm. With the magnetic rotor 300 having a rotation rate in the above ranges, the etching rate of the lift-off layer 120 and/or the surface roughness of the bottom surface 140a of the semiconductor chip 140 may be more easily controlled. In an example case in which the rotation rate of the magnetic rotor 300 is excessively low, the change of the magnetic field may be insignificant.

While the laminate 100 and the etchant 200 are in contact with each other, a plurality of magnetic fields induced by a plurality of magnetic rotors 300 may be applied to the laminate 100 and/or the etchant 200. By applying a plurality of magnetic fields while the laminate 100 and the etchant 200 are in contact with each other, the etching rate of the lift-off layer 120 and/or the surface roughness of the bottom surface 140a of the semiconductor chip 140 being prepared may be more easily controlled. The number of magnetic rotors 300 used to apply a magnetic field may be, for example, about 1 to about 100, about 2 to about 20, or about 3 to about 10.

The laminate 100 and the etchant 200 may be provided to contact with each other. For example, the laminate 100 and the etchant 200 may be provided to contact with each other, for example, in a chamber 400.

The laminate 100 may include a substrate 110, a lift-off layer 120 on the substrate 110, and a semiconductor layer 130 on the lift-off layer 120.

The substrate 110 may be, for example, a sapphire (Al₂O₃) substrate 110, a silicon (Si) substrate 110, a gallium arsenide (GAAs) substrate 110. Sapphire is a crystal having Hexa-Rhombo R3c symmetry, of which lattice constants in c-axial and a-axial directions are 13.001 A and 4.758 A, respectively, and which has a crystal planes, such as plane (0001), plane (1120), and plane (1102). However, the disclosure is not limited thereto, and as such, may be another type of substrate. For example, the substrate 110 may utilize any substrate available in the art that is capable of growing the semiconductor layer 130 having excellent crystallinity. The silicon substrate 110 may be, for example, crystalline silicon. For example, the silicon substrate 110 may have plane (111) plane in a thickness direction of the substrate 110 and plane (110) in a length direction perpendicular to the thickness direction of the substrate 110.

The lift-off layer 120 may be a layer dissolvable by the etchant 200. As the lift-off layer 120 is selectively dissolved by the etchant 200, thereby chemically lifting (or removing) the semiconductor layer 130 off from the substrate 110, the semiconductor chip 140 may be prepared. For example, the lift-off layer 120 may be formed of the same material as the substrate 110, and may be a part of the substrate 110 (as illustrated by the dashed line in FIG. 2). For example, by introducing the semiconductor layer 130 onto a first area on a surface of the silicon substrate 110, and then selectively etching a second area (e.g., the remainder area) where the semiconductor layer 130 is not introduced, it may be possible to introduce a step between the first area with the semiconductor layer 130 and the second area without the semiconductor layer 130. A thickness of the lift-off layer 120 formed from the silicon substrate 110 may be defined by the height of the step between the first area and the second area. For example, the lift-off layer 120 may be formed of a different material from that of the substrate 110. The lift-off layer 120 may be, for example, a scandium nitride (ScN) layer, a gallium nitride (GaN) layer, a silicon oxide (SiO₂) layer, a zirconium (Zr) layer, or a hafnium (Hf) layer, but is not limited thereto. The thickness of the lift-off layer 120 may be, for example, about 0.01 μm to about 10 μm, or about 0.1 μm to about 1 μm.

According to an embodiment, the semiconductor layer 130 may have, for example, a multilayer structure. The semiconductor chip 140 may be formed by separation of the semiconductor layer 130 from the substrate 110. The semiconductor chip 140 may include the bottom surface 140a originating from an area adjacent to the lift-off layer 120, and an outermost surface 140b opposing the bottom surface 140a. The semiconductor layer 130 may have a structure of, for example, about 2 layers to about 20 layers, or about 3 layers to about 10 layers. The semiconductor layer 130 may include a buffer layer in contact with the lift-off layer 120. The buffer layer may be, for example, an AlN layer, a ZnO layer, and the like. However, the disclosure is not limited to the aforementioned examples. For example, the buffer layer may use any material available in the art. The buffer layer may include the bottom surface 140a of the semiconductor chip 140 being separated. The semiconductor layer 130 may include, for example, an n-type semiconductor layer 130, an active layer, a p-type semiconductor layer 130, an n-type electrode, and a p-type electrode. The active layer may have, for example, a quantum well structure, or a multiple quantum well structure. The n-type semiconductor layer 130, the p-type semiconductor layer 130, the n-type electrode, and/or the p-type electrode may include the outermost surface 140b of the semiconductor chip 140 being separated.

The semiconductor layer 130 may be manufactured using methods such as, without being limited to, metal organic chemical vapor deposition (MOCVD), liquid phase epitaxy (LPE), hydrogen liquid phase epitaxy (HVPE), molecular beam epitaxy (MBE), and metal organic vapor phase epitaxy (MOVPE).

The semiconductor chip 140 obtained from the semiconductor layer 130 may include, for example, a light-emitting diode (LED), a complementary metal-oxide semiconductor (CMOS), a CMOS image sensor (CIS), vertical-cavity surface-emitting laser (VCSEL), a photodiode (PD), a memory device, a two-dimensional (2D) material device, and the like. The 2D material may be graphene or a carbon nanotube (CNT). The semiconductor chip 140 may have a micro-size. The micro-size may be 1,000 μm or less, 100 μm or less, or 50 μm or less.

The laminate 100 may include one or more semiconductor layers 130 spaced apart from each other on one substrate 110. Accordingly, removing the lift-off layer from one substrate 110 by the etchant 200 may easily produce a plurality of semiconductor chips.

The etchant 200 may serve to dissolve the lift-off layer 120. The etchant 200 may include an alkaline solution or an acidic solution. The alkaline solution may be, for example, an aqueous solution containing an alkaline compound such as KOH and NaOH. The pH of the alkaline solution may be 10 or higher, 11 or higher, 12 or higher, or 13 or higher. The acidic solution may be an aqueous solution containing an acid such as hydrofluoric acid (HF) and hydrochloric acid (HCl). The pH of the acidic solution may be 4 or less, 3 or less, or 2 or less. In an example case in which the silicon substrate 110 is used, a KOH solution may be used as the etchant 200. In an example case in which a GaAs substrate 110 is used, a HF solution may be used as the etchant 200.

The method in which the laminate 100 and the etchant 200 are made to become in contact with each other is not particularly limited. For example, the laminate 100 may be immersed in the etchant 200. In some embodiments, the etchant 200 may be applied to a part or all of a surface of the laminate 100. The duration of contact between the laminate 100 and the etchant 200 is not particularly limited and may be any time that allows etching of the lift-off layer 120 to proceed. The duration of contact between the laminate 100 and the etchant 200 may be about 0.1 second to about 1 hour. In an example case in which the duration of contact between the laminate 100 and the etchant 200 is too short, removal of the lift-off layer 120 may become difficult. In an example case in which the duration of contact between the laminate 100 and the etchant 200 is too long, the etchant 200 may etch part of the semiconductor layer 130, causing a defect in the semiconductor layer 130. For example, in a case in which the duration of contact between the laminate 100 and the etchant 200 is less than a reference value, removal of the lift-off layer 120 may become difficult. In a case in which the duration of contact between the laminate 100 and the etchant 200 is greater than a reference value, the etchant 200 may etch part of the semiconductor layer 130, causing a defect in the semiconductor layer 130.

The semiconductor chip 140 obtained by applying a magnetic field while the laminate 100 and the etchant 200 are in contact with each other, and then removing the lift-off layer 120 with the etchant 200, may have the bottom surface 140a having an increased roughness. The bottom surface 140a may originate, for example, from a region adjacent to the lift-off layer 120 of the semiconductor layer 130. The bottom surface 140a may be, for example, a peel-off surface of the semiconductor layer 130.

The RMS surface roughness Rq of the bottom surface 140a of the semiconductor chip 140 may be, for example, 1 nm or more, 2 nm or more, 5 nm or more, or 10 nm or more. The RMS surface roughness Rq of the bottom surface 140a of the semiconductor chip may be, for example, about 1 nm to about 400 nm, about 2 nm to about 200 nm or more, about 5 nm to about 100 nm, or about 10 nm to about 50 nm or more. With the bottom surface 140a of the semiconductor chip 140 having the RMS surface roughness Rq in the above range, it may be possible to more effectively prevent the semiconductor chip 140 from adhering to the substrate and prevent aggregation of a plurality of semiconductor chips 140. Accordingly, a process using the semiconductor chip 140 may increase in productivity. In an example case in which the roughness of the bottom surface 140a of the semiconductor chip 140 is too low, the separated semiconductor chip 140 may adhere to the substrate, or a plurality of semiconductor chips 140 may aggregate together, causing defects in a subsequent process such as a transfer process. For example, in a case in which the roughness of the bottom surface 140a of the semiconductor chip 140 is below a reference value, the separated semiconductor chip 140 may adhere to the substrate, or a plurality of semiconductor chips 140 may aggregate together, causing defects in a subsequent process such as a transfer process.

The RMS surface roughness Rq of the bottom surface 140a of the semiconductor chip 140 may be, for example, 50% or less, 40% or less, 30% or less, 20% or less, 10% or less, or 5% or less, of a thickness of a bottom layer 141 including the bottom surface 140a. The RMS surface roughness Rq of the bottom surface 140a of the semiconductor chip 140 may be, for example, about 0.01% to about 50%, about 0.05% to about 40%, about 0.1% to about 30%, about 0.1% to about 20%, about 0.1% to about 10%, or about 0.1% to about 5%, of a thickness of the bottom layer 141 including the bottom surface 140a. In an example case in which the RMS surface roughness Rq of the bottom surface 140a is increased excessively, a defect may occur on the bottom layer 141 and cause a problem in a subsequent process. The bottom layer 141 may be, for example, a buffer layer, a seed layer, a p-type semiconductor layer 130, or the like, but is not limited to the aforementioned examples.

The RMS surface roughness Rq of the bottom surface 140a of the semiconductor chip 140 may increase as the magnitude of the magnetic field increases, for example. The RMS surface roughness Rq of the bottom surface 140a of the semiconductor chip 140 and the magnitude of the magnetic field may be in a proportional relationship. For example, the RMS surface roughness Rq of the bottom surface 140a may be increased by increasing the magnitude of the magnetic field. The ratio Rq1/Rq2 of a first RMS surface roughness Rq1 of the bottom surface 140a of the semiconductor chip 140 obtained by applying a magnetic field during etching to a second RMS surface roughness Rq2 of the bottom surface 140a of the semiconductor chip 140 obtained without application of a magnetic field during etching may be, for example, 2 or more, 4 or more, 10 or more, or 20 or more. The ratio Rq1/Rq2 of the first RMS surface roughness Rq1 of the bottom surface 140a of the semiconductor chip 140 obtained with application of a magnetic field during etching to the second RMS surface roughness Rq2 of the bottom surface 140a of the semiconductor chip 140 obtained without application of a magnetic field during etching may be, for example, about 2 to about 100, about 4 to about 100, about 10 to about 100, or about 20 to about 100. Because the ratio Rq1/Rq2 of the first RMS surface roughness Rq1 of the bottom surface 140a of the semiconductor chip 140 obtained with application of a magnetic field during etching to the second RMS surface roughness Rq2 of the bottom surface 140a of the semiconductor chip 140 obtained without application of a magnetic field during etching has a value in the above ranges, defect formations in the subsequent processes e.g., a transfer process, may be suppressed, thus improving a yield of the transfer process.

The time required to separate the semiconductor chip 140 from the substrate 110 by etching the lift-off layer 120 may decrease, for example, as the magnitude of the magnetic field increases. The etching time of the lift-off layer 120 and the magnitude of the magnetic field may be in an inversely proportional relationship. For example, the etching time of the lift-off layer 120 may be reduced by increasing the magnitude of the magnetic field. The ratio t1/t2 of a first time t1 for separating the semiconductor chip 140 from the substrate 110 by removing the lift-off layer 120 with application of a magnetic field during etching to a second time t2 for separating the semiconductor chip 140 from the substrate 110 by removing the lift-off layer 120 without application of a magnetic field during etching may be, for example, 0.95 or less, 0.9 or less, 0.85 or less. The ratio t1/t2 of a first time t1 for separating the semiconductor chip 140 from the substrate 110 by removing the lift-off layer 120 with application of a magnetic field during etching to a second time t2 for separating the semiconductor chip 140 from the substrate 110 by removing the lift-off layer 120 without application of a magnetic field during etching may be, for example, about 0.1 to about 0.95, about 0.3 to about 0.9 or less, or about 0.5 to about 0.85. Because the ratio t1/t2 of the first time t1 for separating the semiconductor chip 140 from the substrate 110 by removing the lift-off layer 120 with application of a magnetic field during etching to the second time t2 for separating the semiconductor chip 140 from the substrate 110 by removing the lift-off layer 120 without application of a magnetic field during etching has a value in the above ranges, damage to the semiconductor chip 140 caused by etching during etching may be suppressed, thus improving a yield of the semiconductor chip 140 being manufactured.

One or more from the lift-off layer and the semiconductor layer 130 may include a magnetic material. Because the lift-off layer and/or the semiconductor layer 130 includes a magnetic material, the lift-off layer and/or the semiconductor layer 130 may be subject to a physical interference, e.g., a magnetic force due to a magnetic field applied during etching. Because the lift-off layer 120 and/or the semiconductor layer 130 includes a magnetic material, the etching rate and/or surface roughness of a peel-off surface of the peeled semiconductor chip 140 may be more easily controlled by a magnetic field applied during etching. The magnetic susceptibility of the magnetic materials may have, at 25° C. and 1 atm, an absolute value of, for example, 1×10⁻⁵ or more, 1×10⁻³ or more, 1×10⁻¹ or more, 1 or more, 10 or more, 100 or more, or 1×10³ or more. Because the magnetic material has a magnetic susceptibility in the above ranges, the etching rate and/or surface roughness of the peel-off surface of the peeled semiconductor chip 140 may be more easily controlled by a magnetic field applied during etching. The magnetic material may include, for example, a ferromagnetic material. In some embodiments, the magnetic material may include, for example, a diamagnetic material, a paramagnetic material, or a combination thereof. The magnetic material may include, for example, nickel (Ni), iron (Fe), cobalt (Co), tungsten (W), or an alloy thereof.

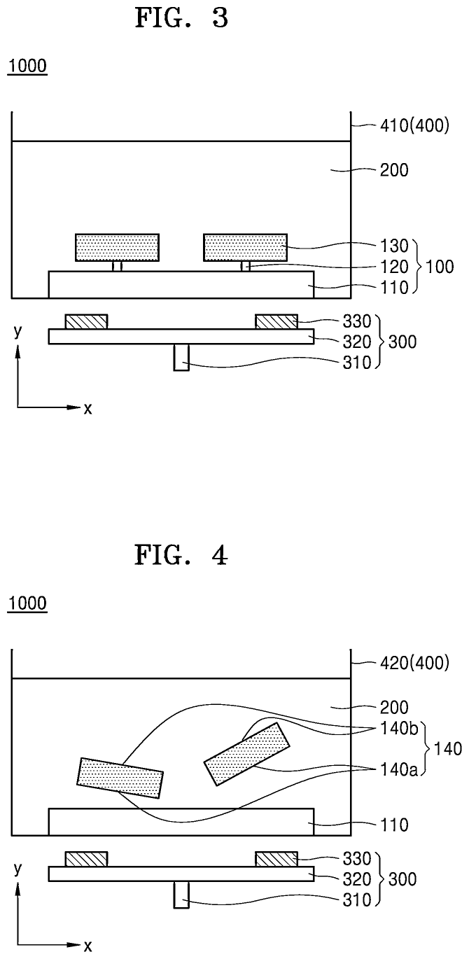

Referring to FIGS. 3 and 4, preparing the semiconductor chip 140 may include, for example: removing a portion of the lift-off layer 120 with an etchant 200 by applying a magnetic field while the laminate 100 and the etchant 200 are in contact with each other in the first chamber 400, to thereby prepare a partially-etched laminate 100, providing the partially-etched laminate 100 to a second chamber 420, and further removing the remainder of the lift-off layer 120 with the etchant 200 by applying a magnetic field while the partially-etched laminate 100 and the etchant 200 are in contact with each other in the second chamber 420, to thereby separate the semiconductor chip 140 from the substrate 110.

The partially-etched laminate 100 may be prepared by removing a portion of the lift-off layer 120 with the etchant 200 by applying a magnetic field while the laminate 100 and the etchant 200 are in contact with each other in the first chamber 410. The laminate 100 may be placed in the first chamber 410, and the etchant 200 may be supplied into the chamber, thereby the laminate 100 and the etchant 200 are in contact with each other. For example, the laminate 100 may be completely immersed in the etchant 200. A portion of the lift-off layer 120 may be etched while applying a magnetic field to the first chamber 410. Because a portion of the lift-off layer 120 is etched, the semiconductor layer 130 remains attached to the substrate 110. For example, about 50% to about 95%, about 70% to about 90%, or about 80% to about 90% of the total area of the lift-off layer 120 may be etched in the first chamber 410. Because impurities are present in the etchant 200 as etching products during etching in the first chamber 410, in an example case in which separated from the substrate 110 by completely etching the lift-off layer 120, a surface of the semiconductor chip 140, may become contaminated with such impurities. Accordingly, the partially-etched laminate 100 may be prepared by partially removing the lift-off layer 120 in the first chamber 410.

The partially-etched laminate 100 may be taken out of the first chamber 410 and provided to the second chamber 420. Before being placed into the second chamber 420, the partially-etched laminate 100 taken out of the first chamber 410 may be rinsed with distilled water once or more, to further remove impurities produced as a result of etching. While the partially-etched laminate 100 and the etchant 200 are in contact with each other in the second chamber 420, a magnetic field may be applied to further remove the remainder of the lift-off layer 120 with the etchant 200 to thereby separate the semiconductor chip 140 from the substrate 110.

The partially-etched laminate 100 may be provided and a new etchant 200 may be supplied to the second chamber 420 to bring the laminate 100 and the etchant 200 into contact with each other. For example, the laminate 100 may be completely immersed in the etchant 200. In some embodiments, the laminate 100 and the etchant 200 may be brought into contact with each other by supplying a continuous or discontinuous flow of the etchant 200 onto the laminate 100. The semiconductor chip 140 to be separated from the substrate 110 may be prepared by further removing the remainder of the lift-off layer 120 with the etchant 200 while applying a magnetic field to the second chamber 420.

The etchant 200 used in the first chamber 410 and the etchant 200 used in the second chamber 420 may have the same or different composition and concentration from each other. The composition and concentration of the etchant 200 used in each of the first chamber 410 and the second chamber 420 may be controlled, depending on a required etching time and/or roughness of the bottom surface 140a of the semiconductor chip 140, and the like. For example, the concentration of the etchant 200 used in the first chamber 410 may be the same as or higher than the concentration of the etchant 200 used in the second chamber 420. In some embodiments, the concentration of the etchant 200 used in the first chamber 410 may be the same as or lower than the concentration of the etchant 200 used in the second chamber 420.

The separated semiconductor chip 140 may be recovered. For example, the separated semiconductor chip 140 may be discharged together with the etchant 200 through an outlet located at a lower end of the second chamber 420. The discharged semiconductor chip 140 may be recovered, for example, through a filtration device 700 provided at the outlet. The filtration device 700 may be, for example, a porous substrate. The filtration device 700 may be a mesh-shaped substrate, for example. The recovered semiconductor chip 140 may be further washed with, for example, distilled water and the like.

A semiconductor chip according to another embodiment may include a bottom layer, and an upper semiconductor layer provided on one side of the bottom layer. The other side of the bottom layer may have a surface roughness Rq (root mean square roughness (RMS)) of 1 nm or more. The surface roughness Rq of the other side of the bottom layer may be 50% or less of a thickness of the bottom layer. Because the surface roughness of the other side of the bottom layer of the semiconductor chip has a Rq (root mean square roughness (RMS)) of 1 nm or more, transfer efficiency during a transfer process of a semiconductor chip may improve. In an example case in which the surface roughness of the other side of the bottom layer of the semiconductor chip (which is light-emitting semiconductor chip) has an Rq (root mean square roughness (RMS)) of 1 nm or more, the light-emitting semiconductor chip may have improved luminous efficiency.

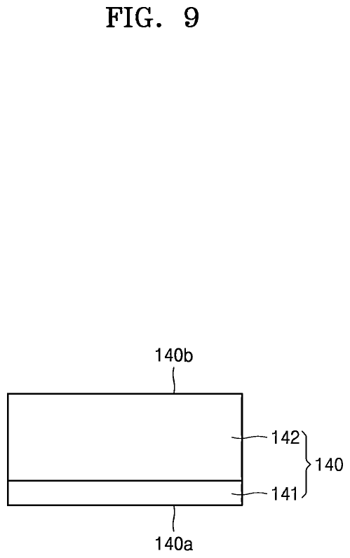

FIG. 9 is a diagram for describing a semiconductor chip according to an embodiment.

Referring to FIG. 9, a semiconductor chip according to an embodiment will be described.

The semiconductor chip 140 may include a bottom layer 141 and an upper semiconductor layer 142 provided on one side of the bottom layer 141. The other side of the bottom layer 141 may have a surface roughness Rq (root mean square roughness (RMS)) of 1 nm or more. The surface roughness Rq of the other side of the bottom layer 141 may be 50% or less of a thickness of the bottom layer 141. The surface roughness Rq of the other side of the bottom layer 141 of the semiconductor chip 140 may be, for example, 1 nm or more, 2 nm or more, 5 nm or more, or 10 nm or more. The surface roughness Rq of the other side of the bottom layer 141 of the semiconductor chip 140 may be, for example, about 1 nm to about 400 nm, about 2 nm to about 200 nm or more, about 5 nm to about 100 nm, or about 10 nm to about 50 nm or more. Because the other side of the bottom layer 141 of the semiconductor chip 140 has a surface roughness in the above ranges, transfer efficiency during a transfer process of the semiconductor chip 140 may further improve. In an example case in which the surface roughness of the other side of the bottom layer 141 of the semiconductor chip 140 is too low, transfer efficiency of the semiconductor chip 140 may deteriorate. For example, in a case in which the surface roughness of the other side of the bottom layer 141 of the semiconductor chip 140 is below a reference value, transfer efficiency of the semiconductor chip 140 may deteriorate.

The surface roughness Rq of the other side of the bottom layer 141 of the semiconductor chip 140 may be, for example, 50% or less, 40% or less, 30% or less, 20% or less, 10% or less, or 5% or less, of the thickness of the bottom layer 141. The surface roughness Rq of the bottom surface 140a of the semiconductor chip 140 may be, for example, about 0.01% to about 50%, about 0.05% to about 40%, about 0.1% to about 30%, about 0.1% to about 20%, about 0.1% to about 10%, or about 0.1% to about 5%, with respect to the thickness of the bottom layer 141. In an example case in which the surface roughness of the bottom surface 140a is increased excessively, a defect may occur on the bottom layer 141 and cause problems in a subsequent process.

The bottom layer 141 may be, for example, a buffer layer, a seed layer, or the like, but is not limited to the aforementioned examples. The bottom layer 141 may be the semiconductor layer 130. The bottom layer 141 may be, for example, a p-type semiconductor layer 130, an n-type semiconductor layer 130, or an intrinsic semiconductor layer 130. The bottom layer 141 may be any layer that can effectively prevent the semiconductor layer 130 provided on the bottom layer 141 from being etched, by having acid resistance or alkali-resistance, during an etching process. The bottom layer 141 may be, for example, an AlN layer. Because the bottom layer 141 due to being an AlN layer has excellent alkali-resistance to an alkaline etchant 200, defect formation in the semiconductor layer 130 by an alkaline etchant during an etching process may be effectively suppressed. An upper semiconductor layer 142 may include, for example, a light emitting layer. The upper semiconductor layer 142 may include, for example, a p-type semiconductor layer 130, a light emitting layer, or an n-type semiconductor layer 130. The upper semiconductor layer 142 may have, on one side or both sides thereof, a p-type electrode and an n-type electrode provided, respectively.

One or more from the bottom layer 141 and the upper semiconductor layer 130 may include a magnetic material. The magnetic susceptibility of the magnetic materials may have, at 25° C. and 1 atm, an absolute value of, for example, 1×10⁻⁵ or more, 1×10⁻³ or more, 1×10⁻¹ or more, 1 or more, 10 or more, 100 or more, or 1×10³ or more. Because the magnetic material has a magnetic susceptibility in the above ranges, the etching rate and/or surface roughness of the peel-off surface of the peeled semiconductor chip 140 may be more easily controlled by a magnetic field applied during etching. The magnetic material may include, for example, a ferromagnetic material. In some embodiments, the magnetic material may include, for example, a diamagnetic material, a paramagnetic material, or a combination thereof. The magnetic material may include, for example, nickel (Ni), iron (Fe), cobalt (Co), tungsten (W), or an alloy thereof.

The semiconductor chip 140 including the light-emitting layer may be a light-emitting semiconductor chip 140. The semiconductor chip 140 may include, for example, a light-emitting diode (LED), a complementary metal-oxide semiconductor (CMOS), a CMOS image sensor (CIS), vertical-cavity surface-emitting laser (VCSEL), a photodiode (PD), a memory device, a two-dimensional (2D) material device, and the like.

According to an embodiment, an apparatus for manufacturing a semiconductor chip may be provided, in which a semiconductor chip may be separated from a laminate. The laminate may include a substrate, a lift-off layer on the substrate, and a semiconductor layer on the lift-off layer. The apparatus for manufacturing a semiconductor chip may include a first chamber in which an etchant and a laminate can be brought in contact with each other, and rotatable one or more magnetic rotors for inducing a changing magnetic field. An apparatus for manufacturing a semiconductor chip may be configured to apply a changing magnetic field while an etchant and a substrate are in contact with each other. In an apparatus for manufacturing a semiconductor chip, one or more magnetic rotors may be provided inside a first chamber or adjacent to an outer surface of the first chamber. For example, the apparatus may include a controller configured to control the one or more rotatable magnetic rotors to apply the changing magnetic field while the etchant and the laminate are in contact with each other in the chamber. According to an embodiment, the apparatus may include a memory storing one or more instructions, a program or a software code, and a processor, which executes the one or more instructions (or the software code) to control the operation of the apparatus. For example, the processor may control the one or more rotatable magnetic rotors to apply the changing magnetic field while the etchant and the laminate are in contact with each other in the chamber. However, the disclosure is not limited thereto, and as such, according to other example embodiment, the processor of the controller may be configured to control various other operations of the apparatus or perform various operations and methods of the disclosure.

FIGS. 1 to 8 are diagrams for describing an apparatus for manufacturing a semiconductor chip according to an embodiment.

Referring to FIGS. 1 to 8, an apparatus for manufacturing a semiconductor chip according to an embodiment will be described.

An apparatus 1000 for manufacturing a semiconductor chip may separate a semiconductor chip 140 from a laminate 100, the laminate 100 including a substrate 110, a lift-off layer 120 on the substrate 110, and a semiconductor layer 130 on the lift-off layer 120. The apparatus 1000 may include a first chamber 410. The first chamber 410 may accommodate the etchant 200 and the laminate 100 therein. The etchant 200 and the laminate 100 may be brought into contact with each other in the first chamber 410. The size and shape of the first chamber 410 are not particularly limited, but may have any size and shape that can accommodate one or more laminates 100. The size and shape of the first chamber 410 may be determined depending on the size and shape of the laminate 100 used, the method by which the etchant 200 is supplied, and the like. The apparatus 1000 may include one or more rotatable magnetic rotors 300. The magnetic rotors 300 may induce a changing magnetic field while rotating.

One or more magnetic rotors 300 may be configured to apply a changing magnetic field to the first chamber 410, while the etchant 200 and the laminate 100 are in contact with each other in the first chamber 410. In the apparatus 1000, one or more magnetic rotors 300 may be provided inside the first chamber 410 and/or adjacent to an outer surface of the first chamber 410. In the apparatus 1000, one or more magnetic rotors 300 may be provided inside the first chamber 410 and on an outer surface of the first chamber 410, at the same time. In the apparatus 1000, for example, one or more magnetic bars may be provided inside the first chamber 410, and one or more magnetic rotors 300 may be provided on an outer surface of the first chamber 410.

While one or more magnetic rotors 300 are rotating, a changing magnetic field may be applied to the etchant 200 and/or the laminate 100 in the first chamber 410. This changing magnetic field may induce a physical interference, such as a magnetic force, with respect to the etchant 200 and/or the laminate 100, thereby controlling the etching rate and surface roughness of a peel-off surface of the semiconductor chip 140 being peeled.

The magnetic rotor 300 may include a rotating shaft 310, a support portion 320 extending in a width direction perpendicular to an axial direction of the rotating shaft 310, and a magnet 330 provided on the support portion 320. The magnet may be, for example, a permanent magnet. The shape and number of a permanent magnet 330 are not particularly limited. One or multiple permanent magnets 330 may be provided on one side or both sides of the support portion 320. The permanent magnet 330 may have, for example, a rod shape, a ring shape, a horseshoe shape, a semi-ring shape, a disk shape, a polygonal plate shape, or the like. By changing the shape and number of the permanent magnet 330, the direction and magnitude of a magnetic field applied to the first chamber 410 may be controlled. The support portion 320 may be, for example, disk-shaped, ring-shaped, or the like, but is not limited thereto.

The magnetic field of the permanent magnet 330 may be, for example, 100 G or more, 200 G or more, 300 G or more, 500 G or more, 1,000 G or more, or 1,500 G or more. G represents the unit of magnetic field, Gauss. The magnetic field of the permanent magnet 330 may be, for example, about 100 G to about 1,000 G, about 200 G to about 10,000 G, about 300 G to about 9,000 G, about 500 G to about 8,000 G, about 1,000 G to about 7,000 G, or about 1,500 G to about 5,000 G. Because the permanent magnet 330 has a magnetic field of a magnitude in the above ranges, the etching rate and/or surface roughness of a peel-off surface of the semiconductor chip 140 being peeled may be more easily controlled. In an example case in which the magnetic field of the permanent magnet 330 is too small, the effect of the magnetic field may be insignificant. For example, in a case in which the magnetic field of the permanent magnet 330 is smaller than a reference value, the effect of the magnetic field may be insignificant.

The rotation rate of the magnetic rotor 300 may be, for example, 100 rpm or more, 200 rpm or more, 300 rpm or more, or 500 rpm or more. The rotation rate of the magnetic rotor 300 may be, for example, about 100 rpm to about 10,000 rpm, about 200 rpm to about 5,000 rpm, about 300 rpm to about 3,000 rpm, or about 500 rpm to about 20,000 rpm. Because the magnetic rotor 300 has a rotation rate in the above ranges, the etching rate and/or surface roughness of a peel-off surface of the semiconductor chip 140 being peeled may be more easily controlled. In an example case in which the rotation rate of the magnetic rotor 300 is too low, the change in the magnetic field may be insignificant. For example, in a case in which the rotation rate of the magnetic rotor 300 is lower than a reference value, the change in the magnetic field may be insignificant.

The magnetic rotor 300 may include a rotating shaft, a support portion 320 extending in a width direction perpendicular to an axial direction of the rotating shaft 310, and a magnet 330 provided on the support portion 320. For example, the axial direction of the rotating shaft 310 may be provided to have a normal direction with respect to the bottom surface 140a of the first chamber 410. Because the rotating shaft 310 of the magnetic rotor 300 is provided in such a direction, a magnetic field may be more effectively applied to the laminate 100.

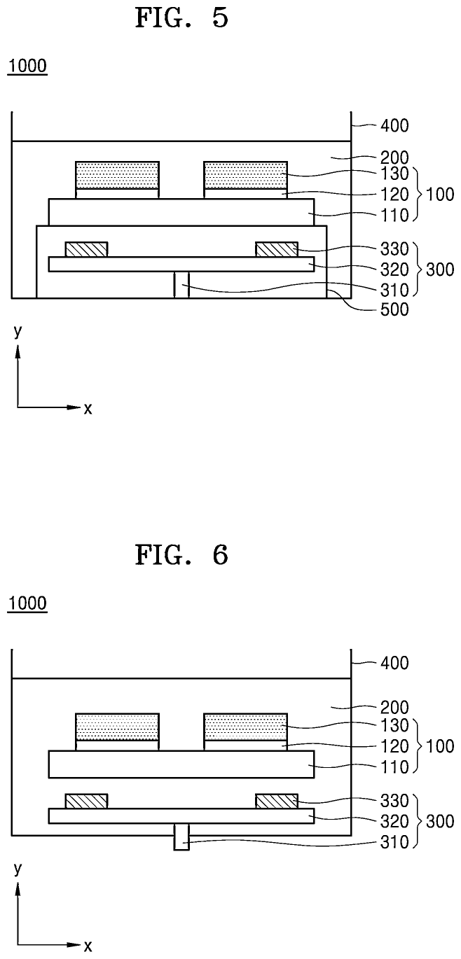

Referring to FIG. 5, according to an embodiment, the magnetic rotor 300 may be accommodated within a housing 500. By being accommodated in the housing 500, it may be possible to effectively protect the magnetic rotor 300 from corrosion by the etchant 200 in the first chamber 410, and the like. The housing 500 may be any housing that can apply a magnetic field induced by the magnetic rotor 300 to the laminate 100 and/or the etchant 200. The housing 500 may be any type that can block penetration of the etchant 200. The housing 500 may be formed of the same material as the first chamber 410, for example. For example, the housing 500 may have a structure including an inner layer formed of the same material as the first chamber 410 and an outer layer having etch resistance on the inner layer.

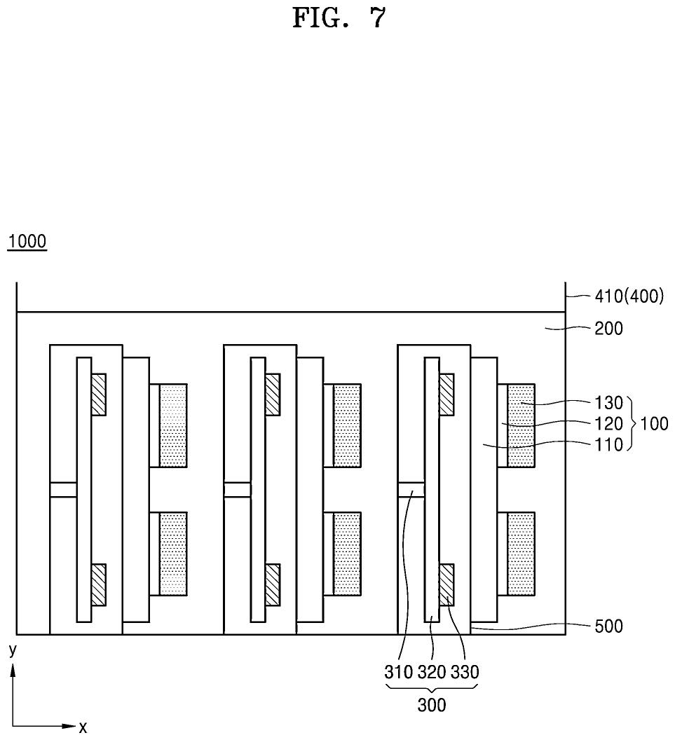

Referring to FIG. 6, according to an embodiment, the magnetic rotor 300 may be provided in the first chamber 410, and the magnetic rotor 300 may rotate within the etchant 200. The surface of the magnetic rotor 300 may be covered with an etch-resistant coating layer while passing a magnetic field. The magnetic rotor 300 may induce agitation of the etchant 200 by rotating within the etchant 200 while applying a magnetic field. By additionally applying agitation of the etchant 200 in addition to the magnetic field within the first chamber 410, the etching rate and/or the surface roughness of the pee-off surface of the semiconductor chip 140 being peeled off may be more easily controlled. In the apparatus 1000 in which the magnetic rotor 300 additionally induces agitation of the etchant 200, the rotation rate of the magnetic rotor 300 may be 100 rpm or more or 100 rpm or less.

Referring to FIG. 7, the first chamber 410 may include one or more magnetic rotors 300 provided inside the first chamber 410. One or more magnetic rotors 300 may each include a rotating shaft 310. An axial direction of one or more rotating shafts 310 may be arranged to be parallel to the bottom surface 140a of the first chamber 410 (x-axis direction in FIG. 7). As the rotating shafts 310 of the magnetic rotors 300 are arranged in the above direction, the number of magnetic rotors 300 that can be accommodated in the first chamber 410 may increase. The number of laminates 100 accommodated in the first chamber 410 may increase, and the number of semiconductor chips 140 that can be separated in the first chamber 410 may increase. As a result, productivity of the apparatus 1000 may increase.

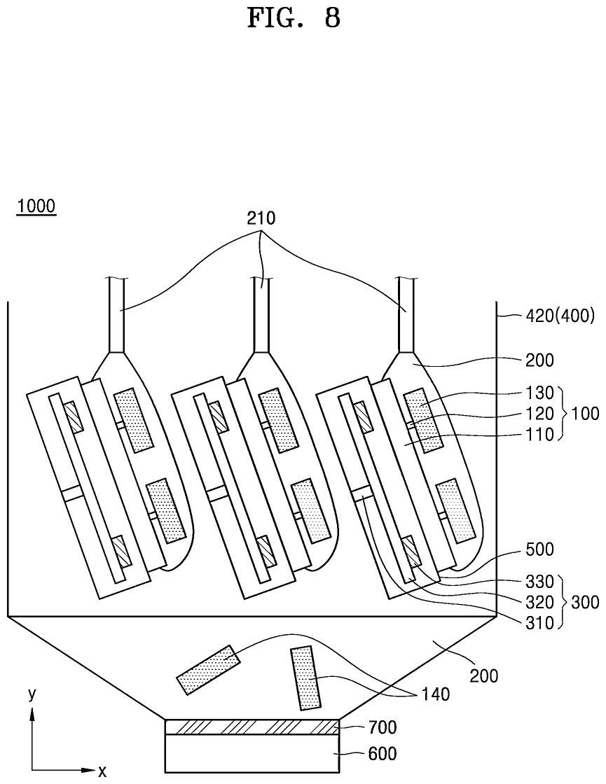

Referring to FIG. 8, the apparatus 1000 for manufacturing a semiconductor chip may further include a second chamber 420 distinguishable from the first chamber 410. In addition, the apparatus 1000 for manufacturing a semiconductor chip may further include one or more magnetic rotors 300 provided inside the second chamber 420. One or more magnetic rotors 300 may each include a rotating shaft 310. The axial direction of at least one rotating shaft 310 may be, for example, a direction parallel to the bottom surface 140a of the second chamber 420 (x-axis direction in FIG. 8) or a direction inclined at less than 90 degrees (direction between x-axis direction and y-axis direction in FIG. 8). The partially-etched laminate 100 may be provided on one or more magnetic rotors 300. One or more etchant supply units 210 may be further included in an upper end of the second chamber 420. By supplying a flow of the etchant 200 while applying a magnetic field to the partially-etched laminate 100 from the etchant supply unit 210, the remainder of the lift-off layer 120 may be further etched from the partially-etched laminate 100 to thereby prepare the semiconductor chip 140 separated from the substrate 110. The rotating shaft of one or more magnetic rotors 300 may be provided in a direction parallel to the bottom surface 140a of the second chamber 420 (x-axis direction in FIG. 8) or in a direction inclined at less than 90 degrees (direction between x-axis direction and y-axis direction in FIG. 8), the semiconductor chip 140 separated by the flow of the etchant 200 and gravity may be collected at a lower end of the second chamber 420.

Referring to FIG. 8, the second chamber 420 may further include an outlet 600 provided on the bottom. The semiconductor chip 140 separated from the substrate 110 may be collected near the outlet 600 on the second chamber 420. The etchant 200 may be discharged out of the second chamber 420 through the outlet 600. The second chamber 420 may further include a filtration device 700 provided adjacent to the outlet 600 to recover the semiconductor chip 140. The filtration device 700 may have, for example, a mesh structure as a porous substrate. The etchant 200 may be discharged through the filtration device 700 and the separated semiconductor chip 140 may be recovered.

The disclosure will be described in greater detail through Examples and Comparative Examples below. However, it will be understood that the following examples are provided merely to illustrate the disclosure, and should not be construed as limiting the scope of the disclosure.

### (Preparation of Laminate (I))

### Example 1: Magnetic Field 273 G

A laminate was placed in the first chamber, and the first chamber was filled with a KOH etchant. The laminate was completely immersed in the etchant.

A magnetic rotor was provided on the outer surface of the bottom of the first chamber. The magnetic rotor included a magnet, and the magnetic field of the magnet was 273 G. The rotation rate of the magnetic rotor was 100 rpm.

The laminate had the structure of substrate/lift-off layer/buffer layer/n-type semiconductor layer/active layer/p-type semiconductor layer.

The substrate was a Si substrate, the lift-off layer was a protrusion of the Si substrate, the semiconductor layer was an AlN layer, the n-type semiconductor layer was an n-type GaN layer, and the active layer had a multiple quantum well structure.

An n-type electrode was provided on the n-type semiconductor layer, and a p-type electrode was provided on the p-type semiconductor layer.

While applying a magnetic field to the first chamber, the etchant selectively etched in the direction of plane (110) of the Si substrate, which is a side surface of the lift-off layer, to remove the lift-off layer and obtain a separated semiconductor chip.

### Example 2: Magnetic Field 602 G

A separated semiconductor chip was obtained in the same manner as in Example 1, except that the magnitude of the magnetic field was changed to 602 G.

### Example 3: Magnetic Field 1686 G

A separated semiconductor chip was obtained in the same manner as in Example 1, except that the magnitude of the magnetic field was changed to 1686 G.

### Example 4: Magnetic Field 273 G+Magnetic Bar

A separated semiconductor chip was obtained in the same manner as in Example 1, except that a magnetic bar was added in the first chamber to further agitate the etchant.

The magnetic bar in the first chamber was rotated by a magnetic rotor on the outer surface of the bottom of the first chamber.

### Comparative Example 1: Magnetic Field 0 G

A semiconductor chip was obtained in the same manner as Example 1, except that no magnetic field was applied.

### Evaluation Example 1: Measurement of Surface Roughness of Peel-Off Surface

The bottom surfaces of the semiconductor chips separated in Examples 1 to 3 were measured for surface roughness, using atomic force microscopy (AFM). The bottom surface was a surface of the separated AlN buffer layer.

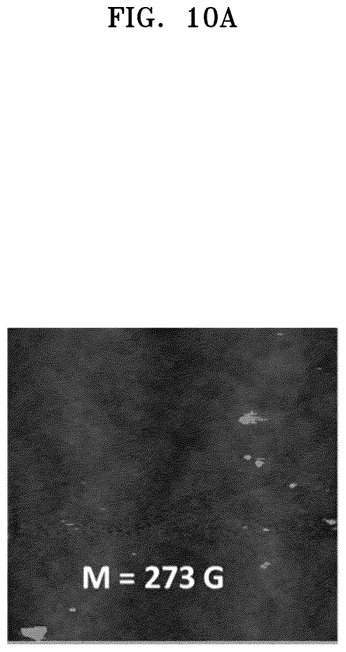

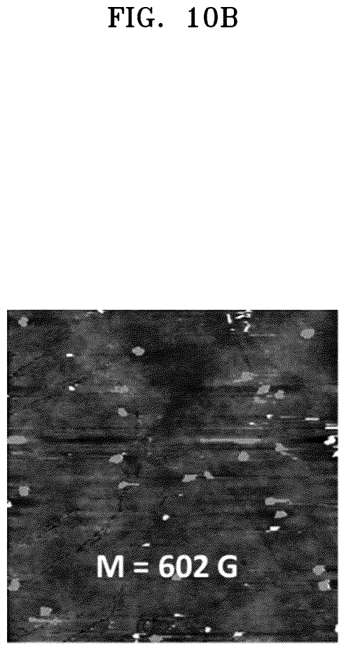

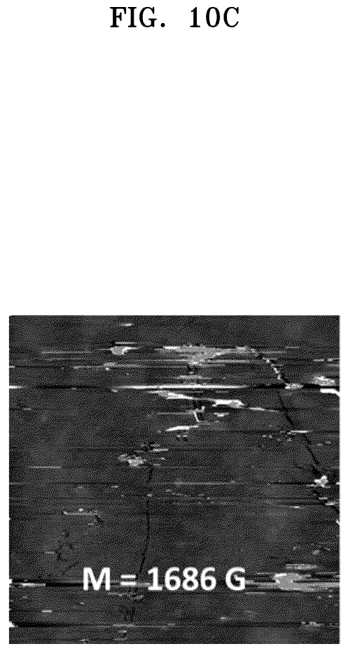

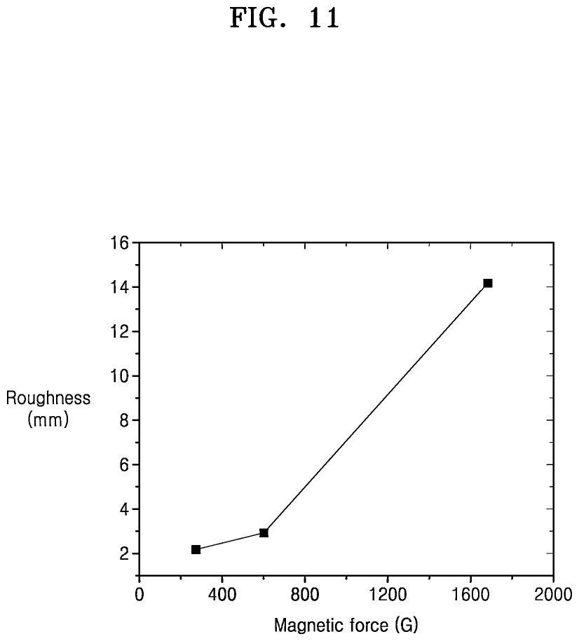

The evaluation results are shown in FIGS. 10A to 10C, FIG. 11, and Table 1.

FIG. 10A is an AFM image of a bottom surface of the semiconductor chip prepared in Example 1.

FIG. 10B is an AFM image of a bottom surface of the semiconductor chip prepared in Example 2.

FIG. 10C is an AFM image of a bottom surface of the semiconductor chip prepared in Example 3.

TABLE 1

| | R_{q} [um] |
|---|---|
| Example 1 | 2.14 |
| Example 2 | 2.92 |
| Example 3 | 14.2 |

As shown in Table 1 and FIGS. 10A to 11, the surface roughness increased as the magnitude of the magnetic field increased in Examples 1 to 3.

It was confirmed that the roughness of a semiconductor chip surface can be controlled by applying a magnetic field during the semiconductor chip manufacturing process.

### Evaluation Example 2: Etching Time Measurement

In Comparative Example 1 and Example 1 and 4, the time required to completely remove the lift-off layer to obtain a separated semiconductor chip (etching time) was measured.

The measurement results are shown in Table 2 below. The etching times of Examples 1 and 4 were expressed as relative values with respect to the etching time of Comparative Example 1 taken as 100.

TABLE 2

| | Etching time |
|---|---|
| Comparative | 100 |
| Example 1 | |
| Example 1 | 85 |
| Example 4 | 80 |

As shown in Table 2, the etching time of the lift-off layer in Examples 1 and 4 was reduced compared to the etching time of the lift-off layer in Comparative Example 1.

It was confirmed that the manufacturing time of semiconductor chips can be shortened by applying a magnetic field during the semiconductor chip manufacturing process.

### (Preparation of Laminate (II))

### Example 5: Surface Roughness Rq=4.51 nm

A separated semiconductor chip was obtained in the same manner as in Example 1, except that the magnitude of the magnetic field was controlled to obtain a semiconductor chip of which the bottom surface has a surface roughness of 4.51 nm.

### Example 6: Surface Roughness Rq=2.54 nm

A separated semiconductor chip was obtained in the same manner as in Example 1, except that the magnitude of the magnetic field was controlled to obtain a semiconductor chip of which the bottom surface has a surface roughness of 2.54 nm.

### Comparative Example 2: Surface Roughness Rq=0.62 nm

A separated semiconductor chip was obtained in the same manner as in Example 1, except that the magnitude of the magnetic field was controlled to obtain a semiconductor chip of which the bottom surface has a surface roughness of 0.62 nm.

### Comparative Example 3: Surface Roughness Rq=0.63 nm

A separated semiconductor chip was obtained in the same manner as in Example 1, except that the magnitude of the magnetic field was controlled to obtain a semiconductor chip of which the bottom surface has a surface roughness of 0.63 nm.

### Evaluation Example 3: Secondary Transfer Yield Measurement

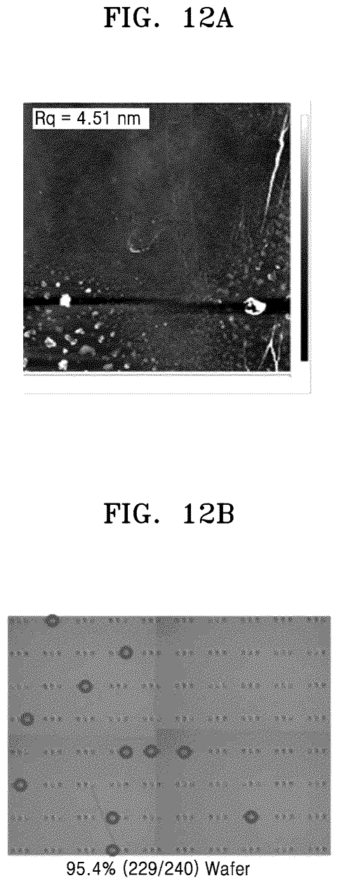

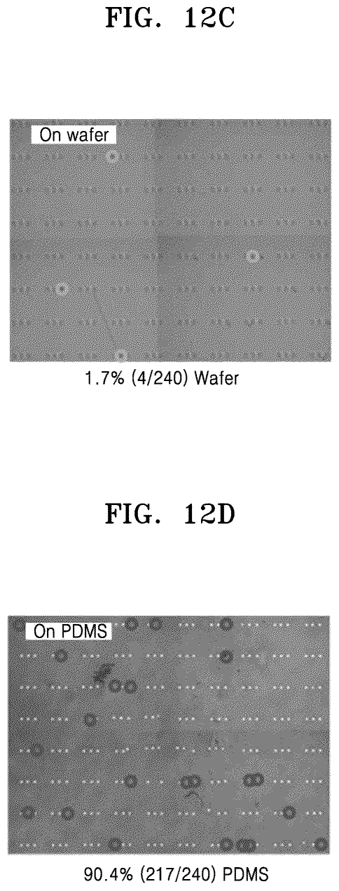

The semiconductor chips manufactured in Examples 5 to 6 and Comparative Examples 2 to 3 were evaluated for primary transfer yield and secondary transfer yield. The evaluation results are shown in FIGS. 12A to 15D and Table 3.

FIG. 12A is an AFM image of a surface of the semiconductor chip manufactured in Example 5.

FIG. 12B is an image of a transfer substrate (e.g., wafer) following a primary transfer, showing the semiconductor chip manufactured in Example 5 aligned on the transfer substrate by the primary transfer.

The method of primary transfer of a semiconductor chip may be carried out according to, for example, a method disclosed in Korean Application Publication No. 2022-0007500. The primary transfer yields are shown in Table 3.

FIG. 12C is an image of the transfer substrate after secondary transfer, showing the semiconductor chip remaining on the transfer substrate after secondary transfer by a polydimethylpolysiloxane (PDMS) sheet.

FIG. 12D is an image of a PDMS sheet after secondary transfer, showing the semiconductor chip transferred onto the PDMS sheet by secondary transfer. The secondary transfer yields are shown in Table 3.

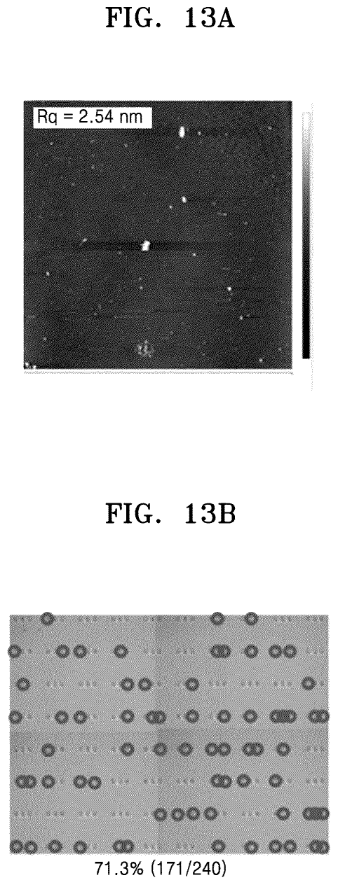

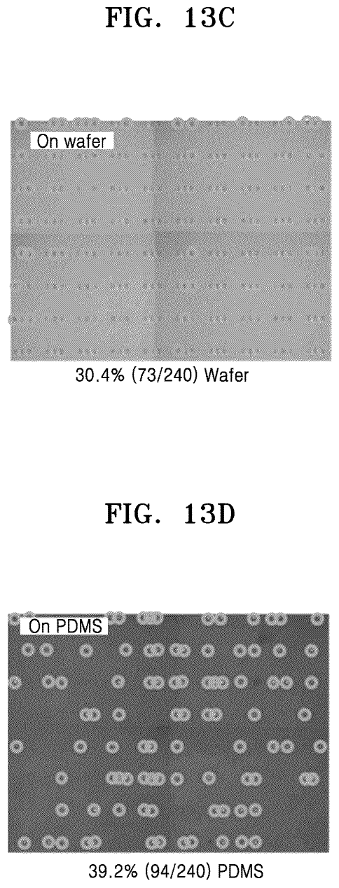

FIG. 13A is an AFM image of a surface of the semiconductor chip manufactured in Example 6, FIG. 13B is an image of a transfer substrate after primary transfer, FIG. 13C is an image of a transfer substrate after secondary transfer, and FIG. 13D is an image of a PDMS sheet after secondary transfer.

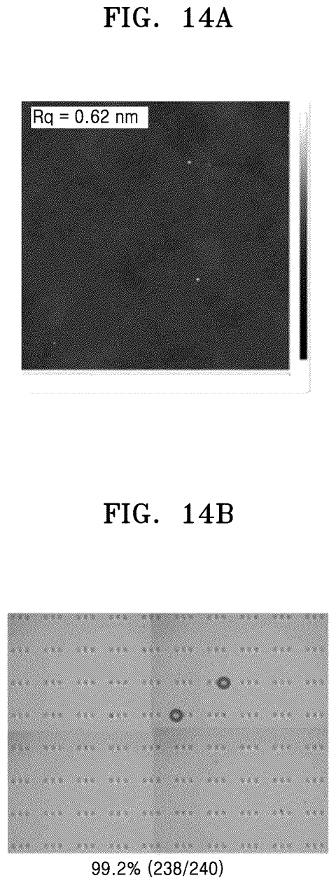

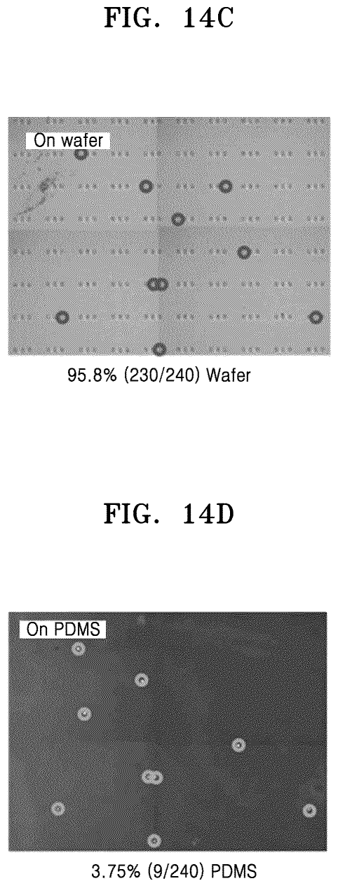

FIG. 14A is an AFM image of a surface of the semiconductor chip manufactured in Comparative Example 2, FIG. 14B is an image of a transfer substrate after primary transfer, FIG. 14C is an image of a transfer substrate after secondary transfer, and FIG. 14D is an image of a PDMS sheet after secondary transfer.

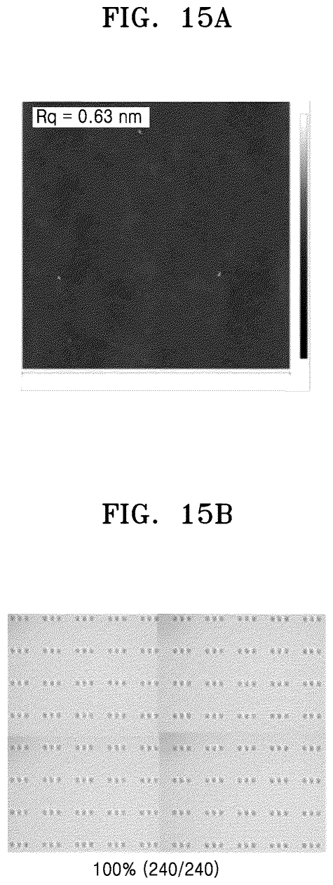

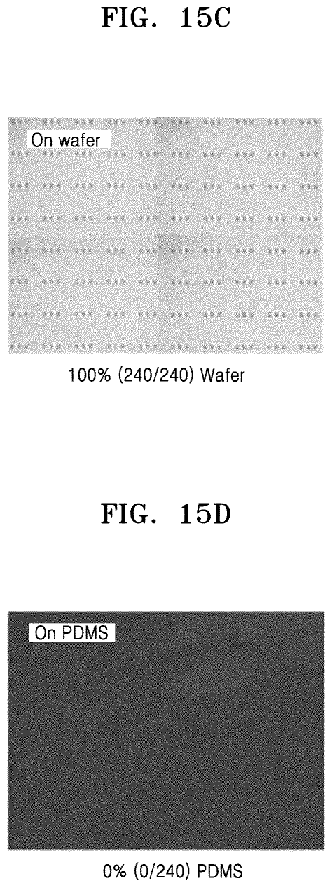

FIG. 15A is an AFM image of a surface of the semiconductor chip manufactured in Comparative Example 3, FIG. 15B is an image of a transfer substrate after primary transfer, FIG. 15C is an image of a transfer substrate after secondary transfer, and FIG. 15D is an image of a PDMS sheet after secondary transfer.

TABLE 3

| | Primary transfer | Secondary transfer |
|---|---|---|
| | yield [%] | yield [%] |
| Example 5 | 95.4 | 90.4 |
| Example 6 | 71.3 | 39.2 |
| Comparative | 99.2 | 3.8 |
| Example 2 | | |
| Comparative | 100 | 0 |
| Example 3 | | |

As shown in Table 3, the semiconductor chips manufactured in Comparative Examples 2 and 3 due to having an excessively low surface roughness of the respective bottom surfaces, were strongly attached to a transfer substrate surface, and thus made secondary transfer virtually impossible.

On the other hand, in the semiconductor chips manufactured in Examples 5 and 6, an increased surface roughness of the bottom surfaces led to decreased adhesion with the transfer substrate surface, thus significantly increasing the efficiency of secondary transfer.

According to one aspect, in a method of preparing a semiconductor chip, the etching time and surface roughness of the peel-off surface can be easily controlled by applying a magnetic field during the etching process of the lift-off layer.

In a semiconductor chip manufactured using this method, defect formation due to etching can be suppressed.

A semiconductor chip manufactured by this method can be easily applied to subsequent processes such as transfer.

It should be understood that embodiments described herein should be only considered for a descriptive purpose and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a semiconductor chip, the method comprising:
providing a laminate into a chamber, the laminate including a substrate, a lift-off layer on the substrate and a semiconductor layer on the lift-off layer;
providing an etchant into the chamber;
removing the lift-off layer with the etchant by applying a magnetic field while the laminate and the etchant are in contact with each other,
wherein the semiconductor layer forms the semiconductor chip after the lift-off layer is removed.

2. The method of claim 1, wherein the magnetic field has a magnitude of 100 G or more.

3. The method of claim 1, wherein the magnetic field comprises a changing magnetic field,
wherein the changing magnetic field is induced by a rotatable magnetic rotor, and
wherein the rotatable magnetic rotor has a rotation rate of 100 rpm or more.

4. The method of claim 1, wherein the etchant comprises an alkaline solution or an acidic solution.

5. The method of claim 4, wherein the alkaline solution comprises KOH, and the acidic solution comprises HF.

6. The method of claim 1, wherein a root mean square (RMS) surface roughness Rq of a bottom surface of the semiconductor chip is 1 nm or more,
wherein the bottom surface originates from a region of the semiconductor layer adjacent to the lift-off layer.

7. The method of claim 6, wherein the RMS surface roughness Rq of the bottom surface is 50% or less of a thickness of a bottom layer including the bottom surface.

8. The method of claim 6, wherein the RMS surface roughness Rq of the bottom surface increases as a magnitude of the magnetic field increases.

9. The method of claim 1, wherein a time for separating the semiconductor layer from the substrate decreases as a magnitude of the magnetic field increases.

10. The method of claim 1, wherein one or more from the lift-off layer and the semiconductor layer comprise a magnetic material,
wherein an absolute value of magnetic susceptibility of the magnetic material is 1×10⁻⁵ or more at 25° C. and 1 atm,
wherein the magnetic material comprises a ferromagnetic material, and
wherein the magnetic material comprises nickel (Ni).

11. The method of claim 1, wherein chamber comprises a first chamber and a second chamber, and
wherein the removing the lift-off layer comprises:
removing a first portion of the lift-off layer with a first etchant by applying a magnetic field while the laminate and the first etchant with each other in the first chamber, to from a partially-etched laminate;
providing the partially-etched laminate into the second chamber; and
removing a remainder of the lift-off layer with a second etchant by applying a magnetic field while the partially-etched laminate and the second etchant in the second chamber, to separate a semiconductor layer from the substrate to form the semiconductor chip.

12. A semiconductor chip comprising:
a bottom layer having a first surface and second surface facing a direction opposite to the first surface; and
an upper semiconductor layer provided on the second surface of the bottom layer,
wherein the first surface of the bottom layer has a root mean square (RMS) surface roughness Rq of 1 nm or more, and
wherein the RMS surface roughness Rq of the first surface of the bottom layer is 50% or less of a thickness of the bottom layer.

13. The semiconductor chip of claim 12, wherein the bottom layer is a buffer layer or a seed layer,
wherein the bottom layer is a semiconductor layer,
wherein the bottom layer is an AlN layer, and
wherein the upper semiconductor layer comprises a light-emitting layer.

14. The method of claim 12, wherein at least one of the bottom layer or the upper semiconductor layer comprises a magnetic material,
wherein an absolute value of magnetic susceptibility of the magnetic material is 1×10⁻⁵ or more at 25° C. and 1 atm,
wherein the magnetic material comprises a ferromagnetic material, and
wherein the magnetic material comprises nickel (Ni).

15. An apparatus for manufacturing a semiconductor chip, the apparatus comprising:
a first chamber configured to house an etchant and a laminate including a substrate, a lift-off layer on the substrate and a semiconductor layer on the lift-off layer;
one or more rotatable magnetic rotors configured to induce a changing magnetic field; and
a controller configured to control the one or more rotatable magnetic rotors to apply the changing magnetic field while the etchant and the laminate are in contact with each other in the first chamber, and
wherein the one or more rotatable magnetic rotors are provided inside the first chamber or adjacent to an outer surface of the first chamber.

16. The apparatus of claim 15, wherein each of the one or more rotatable magnetic rotors comprises one or more permanent magnets,
wherein the one or more permanent magnets have a magnetic field of 100 G or more, and
wherein the one or more rotatable magnetic rotors have a rotation rate of 100 rpm or more.

17. The apparatus of claim 15, wherein each of the one or more rotatable magnetic rotors comprises a rotating shaft,
wherein an axial direction of the rotating shaft is arranged to have a normal direction with respect to a bottom surface of the first chamber.

18. The apparatus of claim 15, comprising one or more magnetic rotors provided inside the first chamber,
wherein each of the one or more magnetic rotors have a rotating shaft,
wherein an axial direction of the rotating shaft is provided to be parallel with respect to a bottom surface of the first chamber.

19. The apparatus of claim 15, further comprising:
a second chamber distinguished from the first chamber; and one or more magnetic rotors provided inside the second chamber,
wherein the one or more magnetic rotors each have a rotating shaft, and an axial direction of the rotating shaft is provided to be parallel or inclined at an angle of less than 90 degrees, with respect to a bottom surface of the second chamber.

20. The apparatus of claim 19, further comprising: an outlet provided on a bottom of the second chamber; and
a filtration device provided adjacent to the outlet to collect the semiconductor chip.
